(19) United States
(12) Patent Application Publication
(10) Pub. No.: US 2006/0289983 A1
(43) Pub. Date: Dec. 28, 2006

(54) System, method and device for reducing electromagnetic emissions and susceptibility from electrical and electronic devices

(75) Inventor: W. Randal Vaughn, Barnard, VT (US)

Correspondence Address: BOURQUE & ASSOCIATES;INTELLECTUAL PROPERTY ATTORNEYS, P.A., 835 HANOVER STREET, SUITE 301, MANCHESTER, NH, 03104, US

(73) Assignee: Silent Solutions LLC, Amherst, NH (US)

(21) Appl. No.: 11/472,736

(22) Filed: Jun. 22, 2006

Related U.S. Application Data
(60) Provisional application No. 60/692,835, filed on Jun. 22, 2005.

(51) Int. Cl. H01L 23/52

(52) U.S. Cl. 257/691

(57) ABSTRACT

A system, device, and method are provided to analyze and provide recommendations regarding electrical noise in circuitry. A rule and algorithm-based recommendation generator may be used to analyze electrical noise at the schematic design stage. The engineer is provided with detailed recommendations of changes to the schematic diagram of the circuit to adjust the electrical noise of the circuit.

### CROSS-REFERENCE TO RELATED APPLICATIONS

The present application claims priority from U.S. provisional patent application Ser. No. 60/692,835, filed Jun. 22, 2005, by W. Randal Vaughn, incorporated by reference herein and for which benefit of the priority date is hereby claimed.

### TECHNICAL FIELD

The present invention relates to a system, method, and device for creating recommended changes to electrical and electronic circuit schematics in order to improve the electromagnetic emissions and immunity performance of devices built from the schematics.

### BACKGROUND INFORMATION

Most electronic products in the U.S. and many countries are regulated by technical standards that restrict the amount of electrical noise (Electromagnetic Interference or EMI) that they may produce. In addition, laws adopted by the European Community and many industrialized nations require that electronic products must be capable of operating in the presence of a prescribed amount of electrical noise. Electronic products produce electrical noise as an unintended consequence of their normal operation, and the area of electrical engineering concerned with electrical noise issues is called Electromagnetic Compatibility (EMC). Engineers designing electronic circuits and products have the education and experience to succeed at making a product function as intended. However, they are not trained and experienced in controlling the unintended electrical noise produced by the product since university electrical engineering curriculums do not traditionally include EMC courses. Therefore, many engineers are unaware of the components and design techniques that should be included to reduce electrical noise. This results in lengthened product development cycles as engineers spend long periods of time attempting to reduce product-generated noise and improve product immunity to external noise through trial and error methods.

Software tools exist that analyze electrical noise from electronic designs at the circuit board layout or post-layout design stage, but there is a need to recommend noise reduction circuits and components at the circuit drawing or “schematic capture” design stage.

### BRIEF DESCRIPTION OF THE DRAWINGS

These and other features and advantages of the present invention will be better understood by reading the following detailed description, taken together with the drawings wherein:

FIG. 1 is an exemplary action database of exemplary Objects, Rules, and Recommendations.

FIG. 2 is an exemplary list of Actions.

FIG. 3 is an exemplary list of Objects.

FIG. 4A-B is an exemplary list of Rules for I/O connectors.

FIG. 5 is an exemplary recommendations list for the I/O connectors as shown in FIG. 4.

FIGS. 6A, 6B, and 6C are flowcharts illustrating an exemplary operation by the invention.

FIG. 7 is a schematic viewer of an exemplary embodiment of the invention.

FIGS. 8 and 9 are the schematic viewer with pop-up windows provided in the schematic viewer according to an exemplary embodiment of the invention.

### DETAILED DESCRIPTION

Aspects of the invention allow the incorporation of noise reduction design techniques developed by experts in the field. Aspects of the invention bring noise reduction expertise to the circuit designer at the beginning stage of development where the beneficial impact to the product cost and schedule is greatest. The engineer is provided with detailed recommendations of changes to the schematic diagram of the circuit. The expert recommendations provided by aspects of the invention greatly increase the likelihood of an on-time product release to the market.

The invention may be a rule and algorithm based recommendation generator for the reduction of electrical noise in circuits. The recommendations may apply to the production and transmission of electrical noise by circuits into the environment, also known as emissions. The recommendations may also apply to the reception of electrical noise by circuits and the effect on the operation of the circuits by the noise, also known as susceptibility or immunity. The recommendations may apply to the production and transmission of electrical noise by circuits into neighboring circuits of the same system, also known as self interference. The recommendations may also apply to the reception of electrical noise by circuits that are neighbors to the noise producing circuits within the same system and the effect on the operation of the circuits by the noise, also known as self interference.

The invention may also be realized in several forms. The invention can be integrated by a software manufacturer into their existing software product that is used to draw circuit diagrams, a process known as “schematic capture”. Noise reduction recommendations may be provided immediately as the relevant circuit components are drawn. The invention may be the basis for a schematic review tool that can “read” a variety of schematic file formats from multiple vendors. That is, software that “reads” a completed or partially complete schematic file or netlist and provides noise reduction recommendations to the user. The schematic file format may be from any of a number of popular vendors. According to this aspect, the tool may be run occasionally by the user to provide recommendations throughout the course of schematic development. Also according to this aspect, the tool can function with schematic capture software from many different vendors and thus has appeal to a broader market place. According to yet another aspect, the invention can be a stand-alone noise reduction design tool. The user may develop noise reduction recommendations for circuits that are representative of those in the schematic design. The user develops a library of often-used circuits that include within them noise reduction techniques, circuits, and components. The user can select the pre-designed circuit building blocks that are designed to meet the functional requirements as well as the electromagnetic emissions and immunity requirements. The noise reduction design can happen before or in conjunction with the development of the schematic diagram.

The invention may be broken down into three elements called Actions. These three elements are Objects, Rules, and Recommendations. Examples of Objects may include, for example, but not limited to, I/O connectors; special net classes such as clocks, strobes, grounds, etc., and power distribution. Properties of Objects may also include, for example, unique identifiers (reference designators, pin numbers, etc.) and electrical characteristics (impedance, frequency, amplitude, source, load, etc.). A Rule determines a change that is applied to an Object based on a principle of noise reduction. The input to a Rule is an Object; the output of a Rule is a Recommendation. For example: apply a shunt capacitive filter of value based on the signal properties (the Rule) on a connector pin (the Object) to reduce common mode noise currents (principle of noise reduction). The Recommendation provides a suggested change to the circuit schematic provided to the user in the form of a circuit schematic and text-based comment. Detailed instructions (see examples in Recommendation List section) may also be provided for each uniquely identified object.

The invention creates an Action database containing the three elements for each Action. A Rule acts on an Object and produces a Recommendation for each line item in the Action database. The invention may include at least one Action list and the user can create additional Action lists. The user can select the most appropriate Action list to apply to the particular schematic design. Action lists may be optimized for particular applications or industries such as: commercial products, military products, automotive products, products containing sensitive circuitry such as radio receivers, etc.

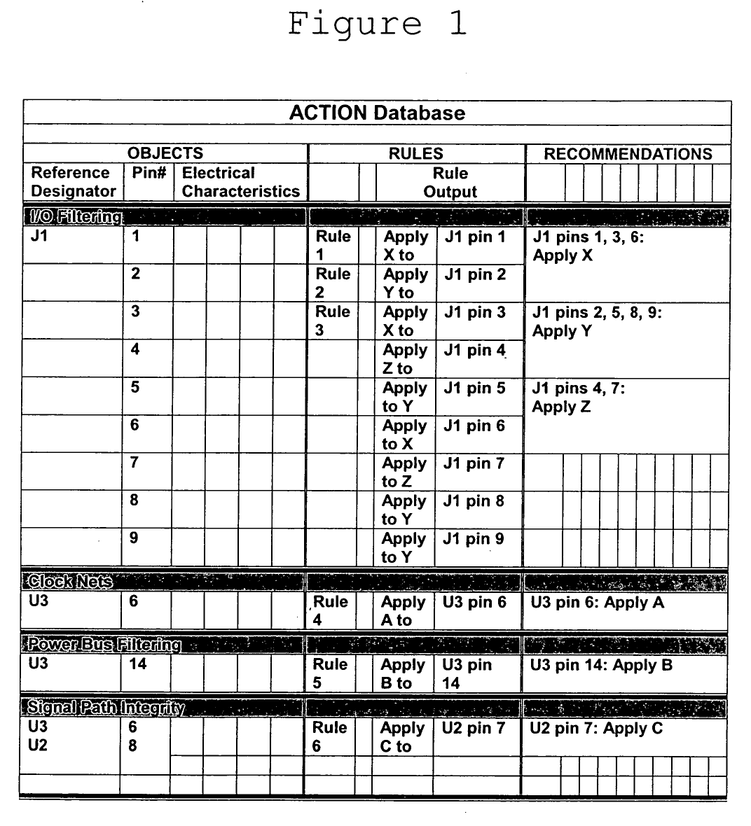

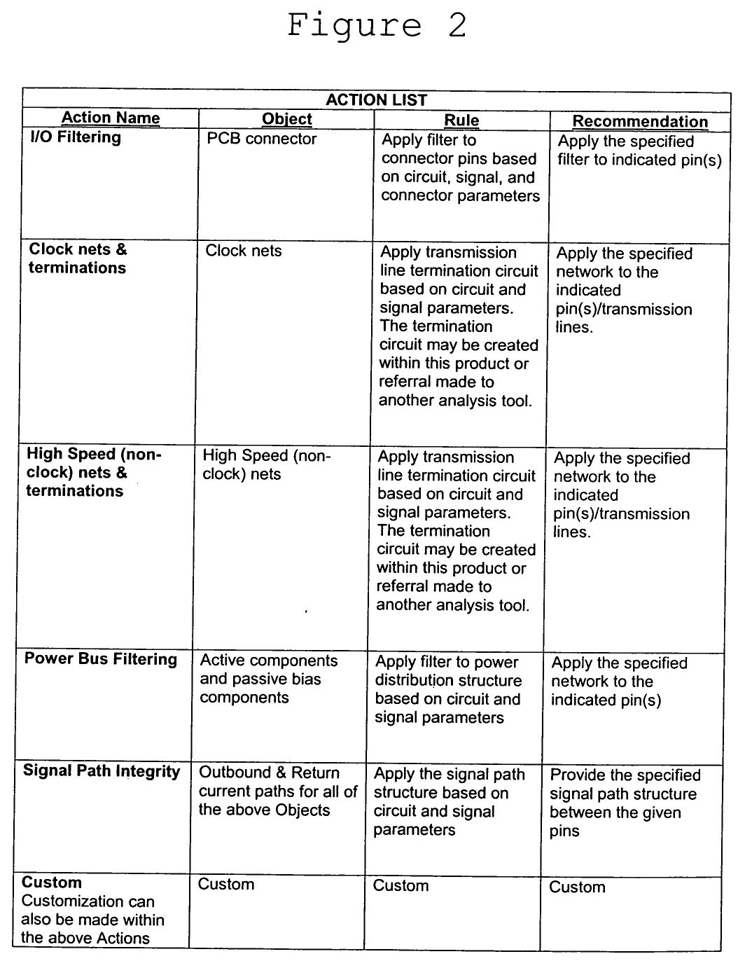

An exemplary Action database, as shown in FIG. 1, organizes and indicates relationships among the Objects, Rules, and Recommendations. A, B, C, X, Y, Z are “short hand” representations used for illustrative purposes. They indicate specific circuits to be applied to the indicated pin or signal path. A partial exemplary list of Actions and the 3 elements for each are shown in FIG. 2. Included is the custom Action that allows users to add their own custom Action item. In addition, the standard items can be altered by the user to create completely customized Actions. Different Action lists can be created and used depending on the application. For example a list of Actions may be produced for class A radiated emissions; Actions for class B radiated emissions; and Actions for Mil-Std 461 immunity, as well as a variety of other categories.

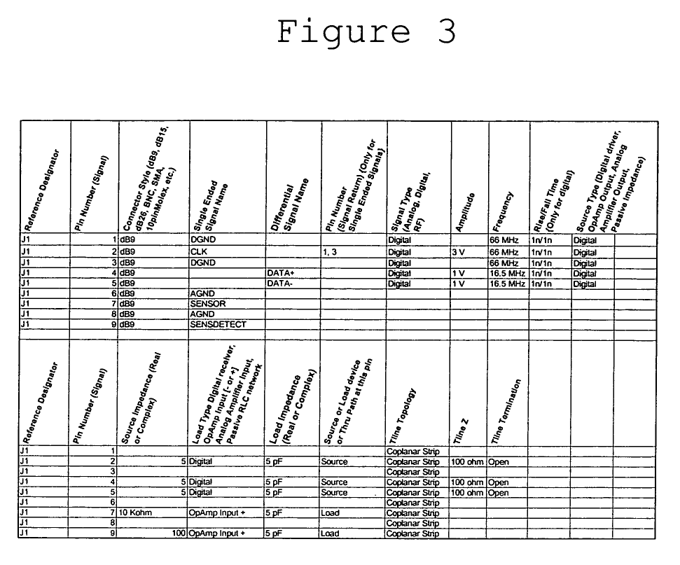

An exemplary list of Objects is shown in FIG. 3. Each object may include its respective electrical characteristics. An Object list may be created for each Object type, i.e. I/O, clocks, power filtering, custom, etc.

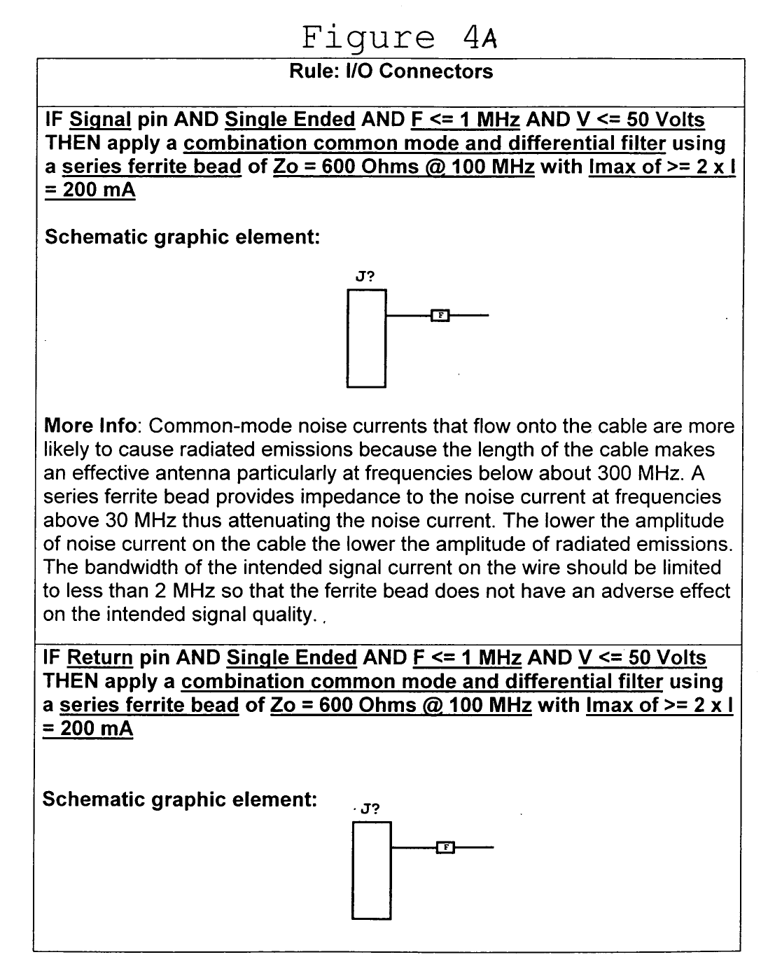

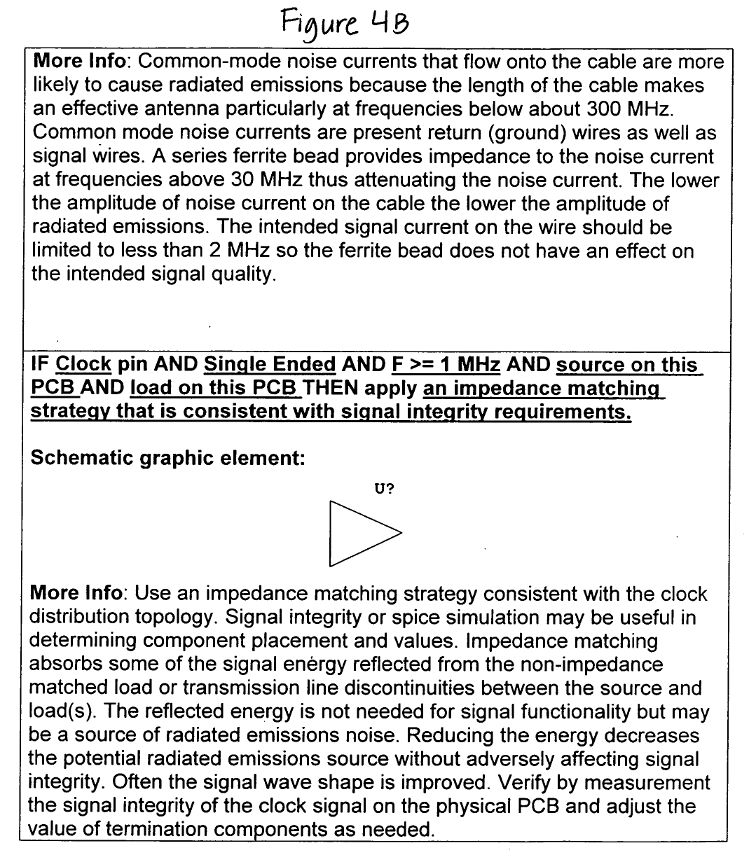

A Rule list is created for each class of Objects, i.e. I/O, clocks, power filtering, custom, etc. An exemplary list of Rules for I/O connectors is shown in FIG. 4. The Rule list provides a sorting process to determine which pins/signals meet particular criteria that are imbedded in the Rules. The electrical characteristics of the Objects are used in some cases to determine component values for the recommended circuits. NOTE: The “More Info” text may be accessed when the user requests additional information about the Recommendation.

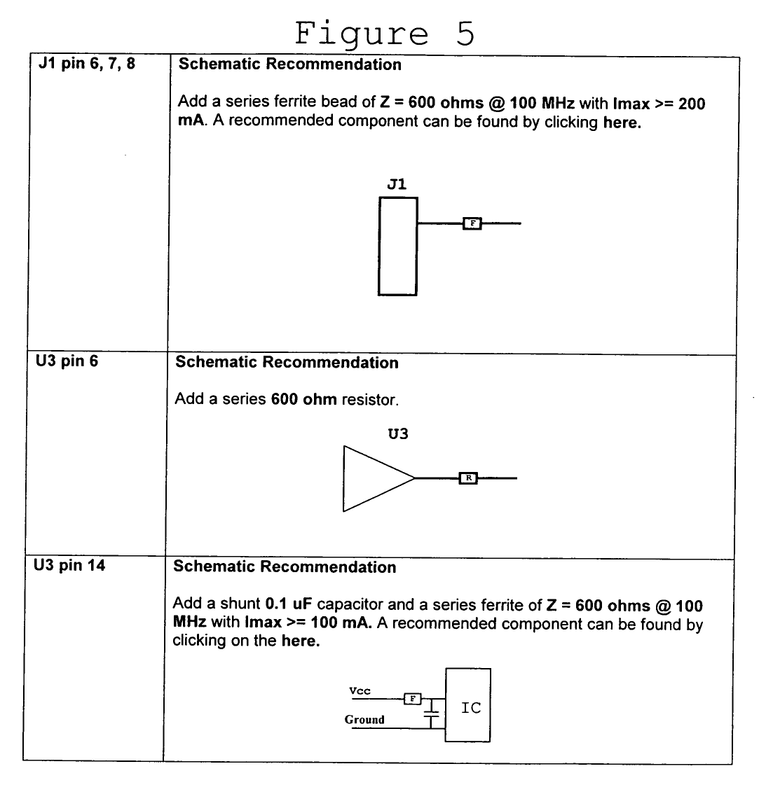

An exemplary Recommendation list for I/O connectors is shown in FIG. 5. The Recommendation list is created for each Object type, i.e. I/O, clocks, power filtering, custom, etc. A hyperlink may be provided to bring the user to a website that provides additional information on the recommended component. The additional information may include, for example, but not limited to, specific component details, manufacturers, component cost, and ordering instructions. Components may include component connections and design characteristics of a circuit.

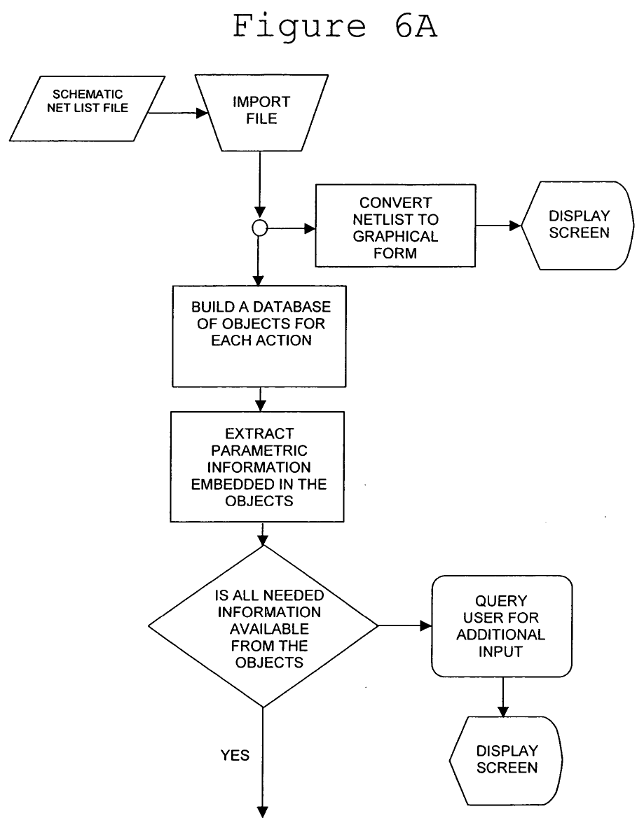

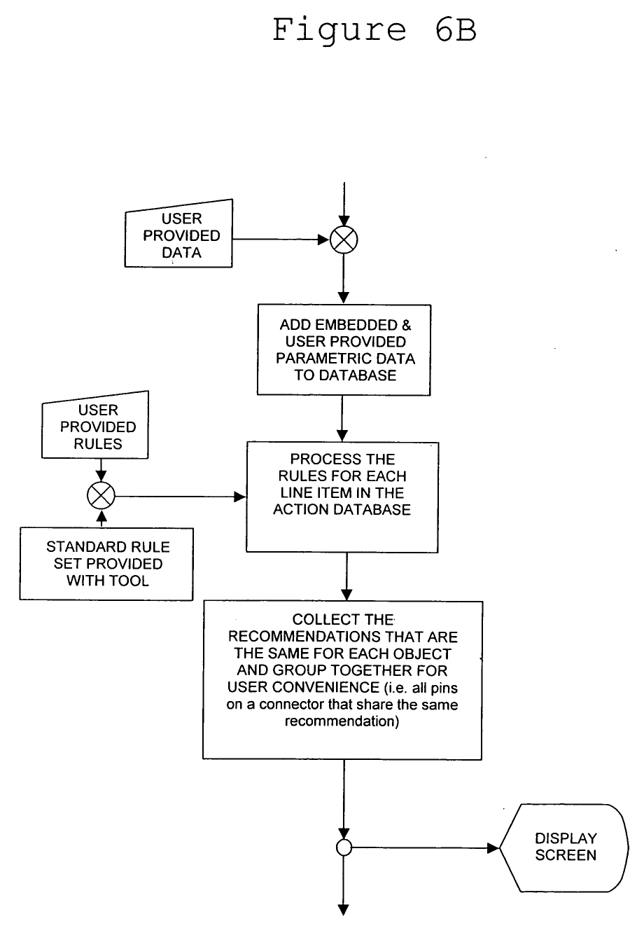

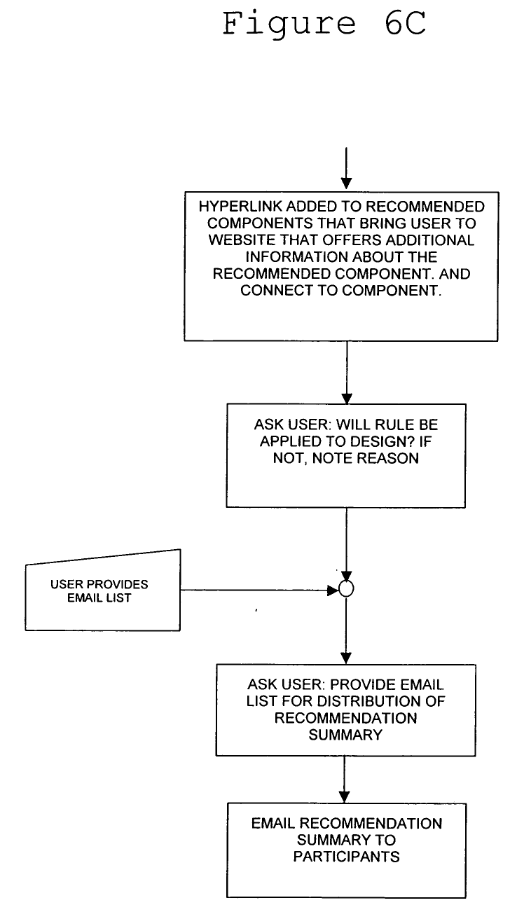

FIGS. 6A, 6B, and 6C show flowcharts of an exemplary operation of the invention. The user inputs the schematic netlist file. The file is imported and the netlist file is converted to graphical form and displayed to the user. The method builds a database of Objects for each Action. The method extracts parametric information embedded in the Objects. The method then determines if all required information has been provided. If additional information is required, the user is prompted via the display screen to enter the additional information and the user enters the additional data. The additional information is included with the embedded parametric data in the Action database. If all required information about the Objects has been provided, the user then selects the Rules. The user may choose the standard Rule set or load customized Rules. The method processes the Rules for each line item in the Action database. The method collects the Recommendations that are the same for each Object and may group them together for the user's convenience. The Recommendations are displayed to the user. Hyperlinks may also be provided to the user allowing the user to access additional information for recommended components. The method may prompt the user on whether to apply the recommended components or design. The user may select which recommended components or designs to incorporate. The user may also provide an email list to send the Recommended Summary. The method transmits an email with the Recommendation Summary to the email participants provided by the user. The analysis is completed and the user may enter a new schematic netlist file for analysis.

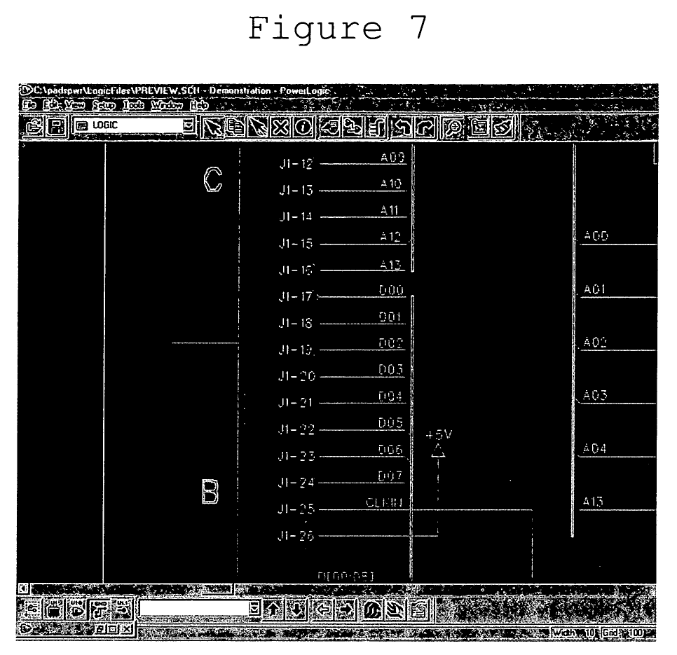

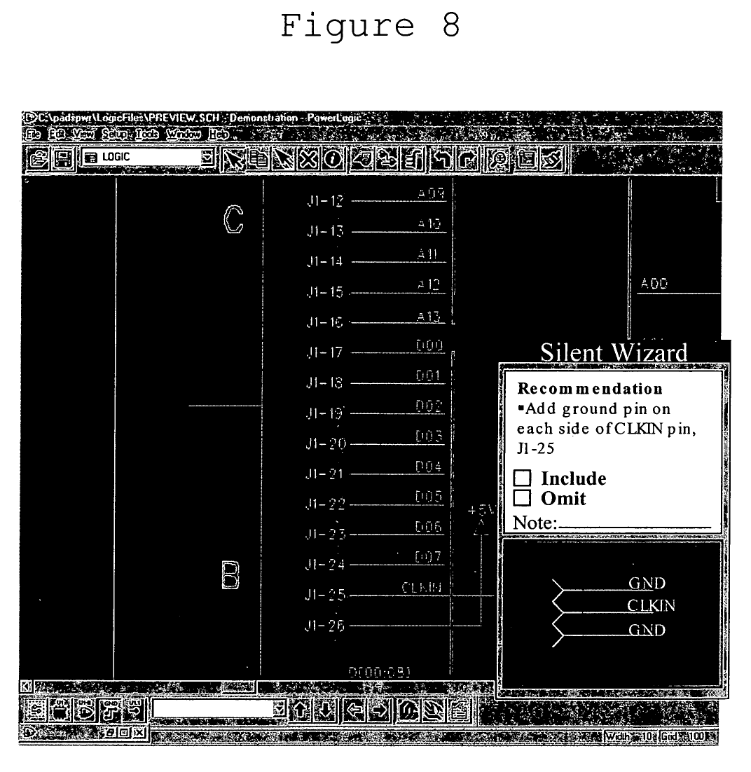

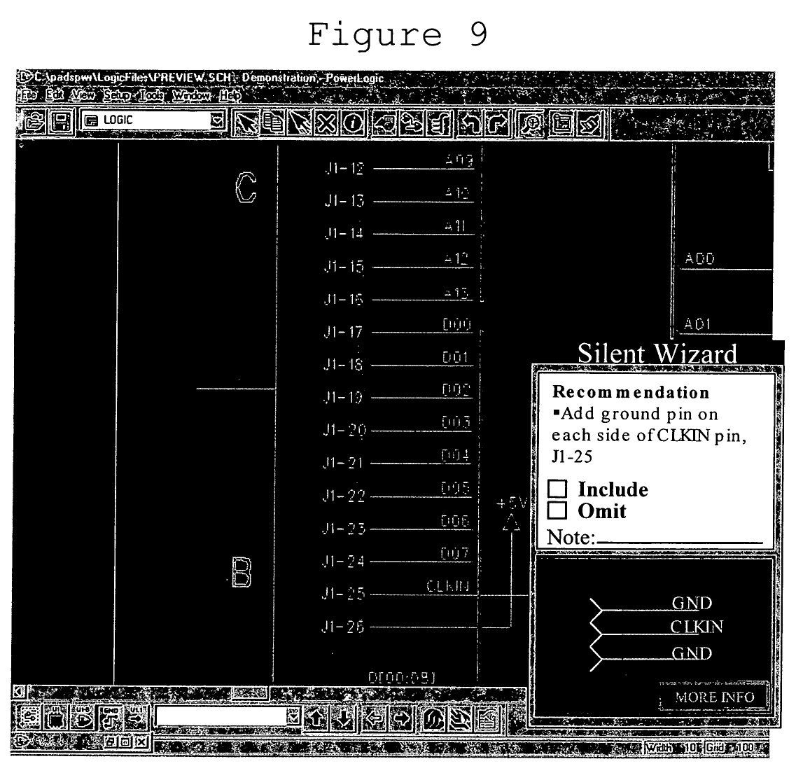

The schematic viewer of an exemplary embodiment of the invention is shown in FIG. 7. The schematic viewer allows a user to enter and analyze a schematic. The schematic viewer allows a user to view the Objects that contribute to the circuit's noise performance and make schematic changes based on predefined expert advice in the form of Rules. A pop-up window in the schematic viewer may be provided in response to noise-critical circuit elements, i.e. connectors, clock lines, transmission lines, differential pairs, etc, as shown in FIG. 8. The pop-up window may provide a recommended circuit, as shown in FIG. 9. The pop-up window may also provide schematic and component values for the Recommended circuit in the schematic viewer. The schematic viewer provides an interface to allow users to enter Objects and Actions and view the Recommendations based on the Objects and Actions. A summary report of all Recommended circuits with the option to email the list to the design team to aid in design reviews may be provided to the user through the schematic viewer.

The Rules maybe customized as previously discussed based on specific applications or requirements, creating a customized knowledge base. The user can modify existing knowledge bases to optimize for a particular application or industry. Third party providers may create unique and more in-depth knowledge bases for a user specific application. Web links within the Recommendations pop-up window of the schematic viewer may bring users to the website of component manufacturers. Subscription based web links may also be provided to noise ratings of popular integrated circuits, as well as customized rules for specific integrated circuit families. The Rules may be exchanged between users to provide a standardized review of a project at the design stage.

Modifications and substitutions by one of ordinary skill in the art are considered to be within the scope of the present invention.

The invention claimed is:

1. A device for creating recommended changes to electrical and electronic circuit schematics at a design stage to improve the electromagnetic emissions and immunity performance of devices built from the schematic comprising:
an input device for receiving one or more schematic netlist attributes;
a memory for storing the netlist, a library of objects and a library of rules, and a library of recommendations;
a processor for receiving the netlist and selecting an object from the library of objects based on the component attributes, applying one or more rules from a library of rules to one or more attributes of the object; and generating a recommendation associated with the applied rule; and
an output device for displaying the recommendation.

2. A device for creating recommended schematic changes at the schematic design stage of claim 1, wherein the processor provides an interface that allows a user to edit one or more objects in the library of objects stored in memory.

3. A device for creating recommended schematic changes at the schematic design stage of claim 1, wherein the processor provides an interface that allows a user to create one or more objects in the library of objects stored in memory.

4. A device for creating recommended schematic changes at the schematic design stage of claim 1, wherein the processor provides an interface that allows a user to edit one or more rules in the library of rules stored in memory.

5. A device for creating recommended schematic changes at the schematic design stage of claim 1, wherein the processor provides an interface that allows a user to create one or more rules in the library of rules in memory.

6. A device for creating recommended schematic changes at the schematic design stage of claim 1, wherein the processor provides an interface that allows a user to select the library of objects from a set of object libraries.

7. A device for creating recommended schematic changes at the schematic design stage of claim 1, wherein the processor provides an interface that allows a user to select the library of rules applied from a set of rule libraries.

8. A device for creating recommended schematic changes at the schematic design stage of claim 1, wherein providing the recommendation involves suggesting a specific replacement component.

9. A device for creating recommended schematic changes at the schematic design stage of claim 1, wherein the inputting device identifies component attributes from an electrical schematic.

10. A device for creating recommended schematic changes at the schematic design stage comprising:
inputting one or more component attributes;
selecting an object from a library of objects to represent the one or more component attribute;
applying one or more rules from a library of rules to one or more attributes of the object; and
supplying a recommendation associated with the applied rule.

11. A device for creating recommended schematic changes at the schematic design stage of claim 10, wherein a user of an application applying the method, edits one or more objects in the library of objects.

12. A device for creating recommended schematic changes at the schematic design stage of claim 10, wherein a user of an application applying the method, creates one or more objects in the library of objects.

13. A device for creating recommended schematic changes at the schematic design stage of claim 10, wherein a user of an application applying the method, edits one or more rules in the library of rules.

14. A device for creating recommended schematic changes at the schematic design stage of claim 10, wherein a user of an application applying the method, creates one or more rules in the library of rules.

15. A device for creating recommended schematic changes at the schematic design stage of claim 10, wherein a user of an application applying the method, selects the library of objects from a set of object libraries.

16. A device for creating recommended schematic changes at the schematic design stage of claim 10, wherein a user of an application applying the method, selects the library of rules from a set of rule libraries.

17. A device for creating recommended schematic changes at the schematic design stage of claim 10, wherein providing the recommendation involves suggesting a specific replacement component

18. A device for creating recommended schematic changes at the schematic design stage of claim 10, wherein the act of inputting component attributes further comprises the action of:
identifying component attributes from an electrical schematic.

19. A device for creating recommended schematic changes at the schematic design stage of claim 10, wherein the act of supplying a recommendation further comprises the action of:
producing an email with a recommendation summary to one or more email participants.

20. A device for creating recommended schematic changes at the schematic design stage of claim 10, wherein the act of supplying a recommendation further comprises the action of:
producing web links to the websites of component manufacturers associated with the recommendation.

21. A device for creating recommended schematic changes at the schematic design stage of claim 10, wherein the act of applying rules further comprises the action of:
providing web links to noise ratings of known integrated circuits.

22. A device for creating recommended schematic changes at the schematic design stage of claim 10, wherein the act of applying rules further comprises the action of:
providing web links to customized rules for specific integrated circuit families.

23. A device for analyzing electromagnetic emissions at the schematic design stage comprising:
inputting means for inputting one or more component attributes;
storage means for storing a library of objects, a library of rules, and a library of recommendations associated with the library of rules;
identifying means for identifying an object from the library of objects to represent the one or more component attributes
processing means applying one or more rules from the library of rules to one or more attributes of the object; and
display means for displaying a recommendation from the library of recommendations based on the applied rule.

24. A device for creating recommended schematic changes at the schematic design stage of claim 23, further comprising:
a means for editing one of the library of objects, library of rules, and library of recommendations based on a user selection.
